(19) United States
(12) Patent Application Publication
(10) Pub. No.: US 2007/0074664 A1
(43) Pub. Date: Apr. 5, 2007

(54) Plasma CVD apparatus and plasma surface treatment method

(75) Inventors: Kazuhito Nishimura, Nangoku-shi (JP); Hideki Sasaoka, Kochi-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignees: KOCHI INDUSTRIAL PROMOTION CENTER, Kochi-shi (JP); CASIO COMPUTER CO., LTD., Tokyo (JP)

(21) Appl. No.: 11/541,306

(22) Filed: Sep. 29, 2006

(30) Foreign Application Priority Data
Sep. 30, 2005 (JP) 2005-289193
Sep. 13, 2006 (JP) 2006-247972

(51) Int. Cl. C23C 16/00

(52) U.S. Cl. 118/723 E

(57) ABSTRACT

A substrate is mounted on a mount surface of an anode in a chamber. A flow path is formed in a cathode facing the anode, and cooling water is circulated therethrough. A voltage is applied across the anode and the cathode to form a layer of carbon nanowall on the substrate by plasma, and thereafter the anode is cooled by a cooling member to rapidly cool the substrate to a predetermined temperature.

### BACKGROUND OF THE INVENTION

1. Field of the Invention

The present invention relates to a plasma CVD apparatus and a plasma surface treatment method.

2. Description of the Related Art

As film forming techniques utilizing direct-current plasma, there are a diamond-like carbon film stack and its manufacturing method, which are described in Unexamined Japanese Patent Application KOKAI Publication No. 2003-113470.

The diamond-like carbon film stack described in the above-indicated publication is used as a field emission electrode, and includes graphite-like carbon lower layers having a high sp² content and diamond-like carbon upper layers having a high sp³ content, which are sequentially stacked on a substrate in this order. According to this manufacturing method, the film thickness of each layer is set by changing the bias to be applied to a negative electrode (cathode).

### SUMMARY OF THE INVENTION

However, according to the manufacturing method of the diamond-like carbon film stack described in the above-indicated publication, the film quality is modulated by modulating the bias voltage. Such a plasma CVD apparatus can change the film quality only moderately, because the temperature of the substrate surface cannot easily be changed drastically by voltage modulation.

An object of the present invention is to provide a plasma CVD apparatus and a plasma surface treatment method which can speedily change the film quality.

To achieve the above object, a plasma CVD apparatus according to a first aspect of the present invention comprises:

a mount table having a mount surface on which a process target is mounted, and a first electrode;

a second electrode facing the first electrode for generating plasma between itself and the first electrode;

a voltage setting unit which applies a voltage between the first electrode and the second electrode; and

a cooling member which takes away heat from the process target.

The plasma CVD apparatus may comprise a temperature measuring unit which measure a temperature of the process target.

In the plasma CVD apparatus, it is preferred that while a first film is growing on the process target by plasma, the cooing member be made to abut on the mount table to cool he mount table, so that a second film different from the first film may be grown on the first film.

Further, while a first film is growing on the process target by plasma, the cooling member may be brought close to the mount table to cool the mount table, so that a second film different from first film may be grown on the first film.

In this manner, the first film may be grown on the process target by plasma before the cooling member takes away heat from the process target, and the second film different from the first film may be grown on the first film by plasma after the cooling member takes away heat from the process target.

The first film may comprise a carbon nanowall.

The second film may contain diamond fine grains.

The cooling member may lower a temperature of the process target by 10° C. or more.

The plasma CVD apparatus may comprise a cooling member moving mechanism which moves the cooling member toward a surface of the mount table that is opposite to the mount surface.

In the plasma CVD apparatus, the cooling member moving mechanism may bring close the cooling member to or make the cooling member abut on the mount table after a first film is grown on the process target by plasma, and may move the cooling member away from the mount table when the mount table is cooled to a predetermined temperature.

To achieve the above object, a plasma surface treatment method according to a second aspect of the present invention comprises procedures of:

generating plasma between a first electrode and a second electrode to apply a first process on a surface of a process target mounted on a mount surface of a mount table; and

taking away heat from the process target by using a cooling member, and applying a second process on the surface of the process target.

In the plasma surface treatment method described above, it is preferred that in the second process, the cooling member be made to abut on the mount table to cool the mount table while a first film is growing on the process target by plasma, and to grow a second film different from the first film on the first film.

Alternatively, in the second process, the cooling member may be brought close to the mount table to cool the mount table while a first film is growing on the process target by plasma, and to grow a second film different from the first film on the first film.

In this manner, it is preferred that in the first process, the first film be grown on the process target by plasma before the cooling member takes away heat from the process target, and in the second process, the second film different from the first film be grown on the first film by plasma after the cooling member takes away heat from the process target.

The first film may comprise a carbon nanowall.

The second film may contain diamond fine grains.

In the plasma surface treatment method described above, a temperature of the process target may be lowered by 10° C. or more by using the cooling member in the second process.

In the plasma surface treatment method described above, the second process may comprise a cooling member moving process of moving the cooling member toward a surface of the mount table that is opposite to the mount surface.

In this case, it is preferred that the cooling member be brought close to or made to abut on the mount table after a first film is grown on the process target by plasma, and the cooling member be moved away from the mount table when the mount table is cooled to a predetermined temperature.

The plasma surface treatment method may comprise:

generating plasma between a first electrode and a second electrode to form a first film comprising a carbon nanowall on a surface of a process target mounted on a mount surface of a mount table; and

taking away heat from the process target by using a cooling member, and forming a second film containing diamond fine grains on the first film.

### BRIEF DESCRIPTION OF THE DRAWINGS

These objects and other objects and advantages of the present invention will become more apparent upon reading of the following detailed description and the accompanying drawings in which:

FIG. 1A and FIG. 1B are structure diagrams showing the overview of a direct-current plasma CVD apparatus according to an embodiment of the present invention;

FIG. 2 is an image obtained by scanning a surface of an electron emission film using a scanning microscope;

FIG. 3 is an expanded image of the electron emission film of FIG. 2;

FIG. 4 is an image showing a cross section of the electron emission film;

FIG. 5 is a diagram showing a field emission electrode;

FIG. 6 is a diagram showing an X-ray diffraction pattern of the electron emission film;

FIG. 7 is a diagram showing a spectrum of a carbon nanowall;

FIG. 8A is a diagram showing temporal changes in plasma exciting power, FIG. 8B is a diagram showing temporal changes in emissivity, and FIG. 8C is a diagram showing temporal changes in the temperature of a surface of a substrate;

FIG. 9 is a diagram showing a Raman spectrum of a carbon film containing aggregates of a plurality of diamond fine grains;

FIG. 10 is a diagram showing field emission characteristics of a diamond film of the present invention and a carbon nanowall of a comparative example;

FIG. 11A and FIG. 11B are diagrams showing expanded images of a diamond film;

FIG. 12A to FIG. 12E are diagrams showing expanded images of some regions in the diamond film;

FIG. 13 is a diagram showing a ratio (carbon having sp³ bonds)/(carbon having sp² bonds) at some positions on the diamond film;

FIG. 14 is a diagram showing correlation between a ratio (carbon having sp³ bonds)/(carbon having sp² bonds) and resistance;

FIG. 15A to FIG. 15D are diagrams showing light emitting stage of some diamond films having different resistances;

FIG. 16A and FIG. 16B are structure diagrams showing the overview of a plasma CVD apparatus in which a gas is supplied from a cooling member;

FIG. 17 is a diagram showing temperature dependency of a substrate when a gas is supplied from the cooling member;

FIG. 18A and FIG. 18B are structure diagrams showing the overview of a plasma CVD apparatus in which a gas is supplied from a cooling member; and

FIG. 19A and FIG. 19B are structure diagrams showing an operation of the cooling member of the plasma CVD apparatus for supplying a gas while cooling a substrate, etc.

### DETAILED DESCRIPTION OF THE PREFERRED EMBODIMENTS

An embodiment of the present invention will be specifically explained below with reference to the drawings.

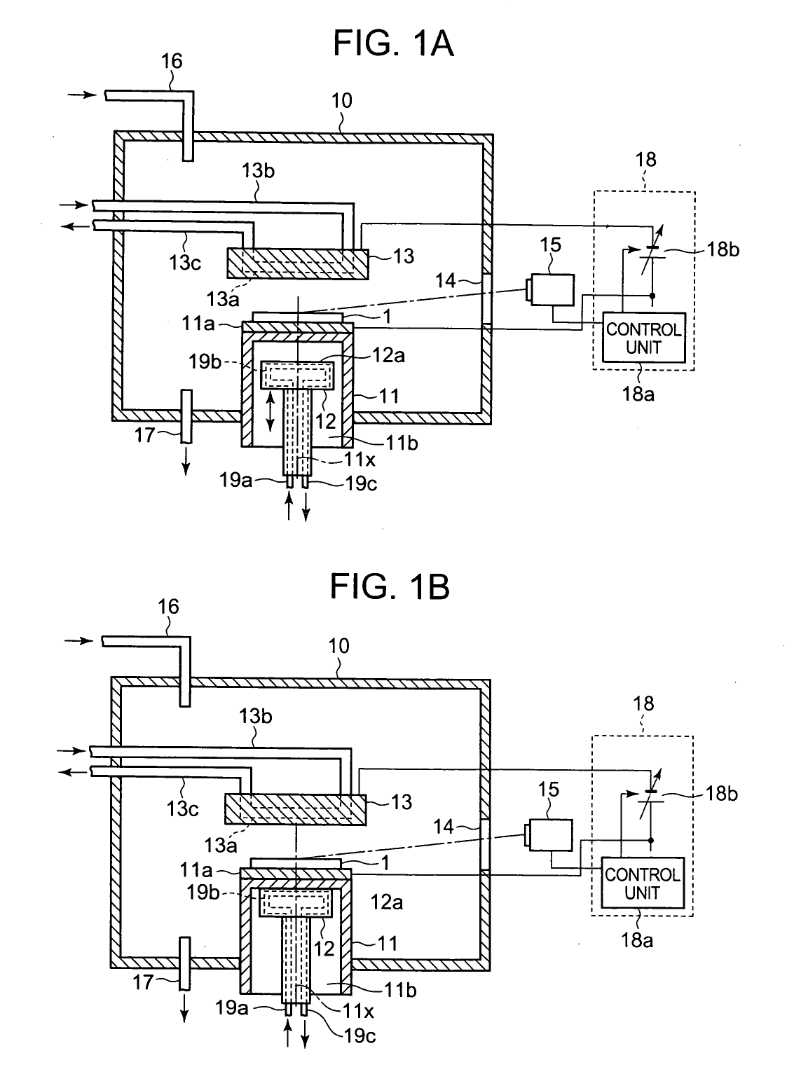

FIG. 1A and FIG. 1B are structure diagrams showing the overview of a direct-current (DC) plasma CVD apparatus according to an embodiment of the plasma CVD apparatus according to the present invention.

The DC plasma CVD apparatus is for forming a film on the surface of a substrate 1 as a process target, and comprises a chamber 10 for shielding the substrate 1 from the external atmosphere.

A stage 11 made of steel is arranged inside the chamber 10. An anode 11 a made of a high melting point metal having a disk shape and a fine thermal conductivity is mounted on the stage 11. The substrate 1 is fixed on the upper mount surface of the anode 11a. The stage 11 is set to rotate together with the anode 11a about an axis 11x. Molybdenum (thermal conductivity: 138 W/m·K, melting point: 2620° C.) is preferred as the metal of the anode 11a.

A closed space 11b is provided under the anode 11a. A cooling member 12 is set inside the space 11b. The cooling member 12 is structured to be freely moved upward and downward along the arrow, by an unillustrated moving mechanism. The cooling member 12 is made of a metal having a high thermal conductivity such as copper, etc. The cooling member 12 has a tube path 19a, a flow path 19b, and a tube path 19c. The cooling member 12 has its entire body cooled by circulating cooled water, cooled calcium chloride aqueous solution, or the like therethrough to enter from the tube path 19a into the flow path 19b and to be drained from the tube path 19c.

Accordingly, when a surface 12a of the cooling member 12 abuts on the lower surface of the stage 11 by the cooling member 12 being moved upward as shown in FIG. 1B, the stage 11 is cooled. Further, the stage 11 cools the anode 11a positioned thereupon, so that the anode 11a can steal heat form the substrate 1. That is, the cooling medium sent from the tube path 19a exchanges heat with the substrate 1 in the flow path 19b near the surface 12a to reduce the temperature of the substrate 1, and the cooling medium having its temperature raised flows from the flow path 19b to the tube path 19c to be drained. The cooling medium drained from the tube path 19c is cooled by an unillustrated cooling device, and circulated to be again set to the tube path 19a. In order that the surface 12a of the cooling member 12 may cool the substrate 1 uniformly in the surface direction, it is preferred that the shape of the surface 12a be similar to that of the substrate 1 and slightly larger than the substrate 1, and that the flow path 19b be structured to circulate the cooling medium so as to make the surface 12a have a uniform temperature.

The space 11b provided under the anode 11a is enclosed by the stage 11, and has a gas sealed thereinside or has an atmosphere of a lower pressure than the barometric pressure.

A cathode 13 is arranged above the anode 11a with a certain distance therebetween. The cathode 13 faces the anode 11a. A flow path 13a through which a cooling medium flows is formed inside the cathode 13, and tube paths 13b and 13c are attached at both the ends of the flow path 13a. The tube paths 13b and 13c penetrate holes formed in the chamber 10 to be connected to the flow path 13a. The holes in the chamber 10 penetrated by the tube paths 13b and 13c are sealed by a sealing agent to secure the airtightness inside the chamber 10. With a cooling medium flowing through the tube path 13b, the flow path 13a, and the tube path 13c, heat generation by the cathode 13 is restricted. It is preferred that water, calcium chloride aqueous solution, or the like be used as the cooling medium.

A window 14 is formed in a side wall of the chamber 10, so that the interior of the chamber 10 can be observed. A heat resistance glass is fitted on the window 14, and the airtightness inside the chamber 10 is further secured. A radiation thermometer 15 for measuring the temperature of the substrate 1 through the glass on the window 14 is placed outside the chamber 10.

The DC plasma CVD apparatus comprises a material system (unillustrated) for introducing a material gas through a gas supply tube path 16, a gas discharge system (unillustrated) for discharging a gas from the chamber 10 through a gas discharge tube path 17 to adjust the gas pressure in the chamber 10, and an output setting unit 18.

The tube paths 16 and 17 penetrate holes formed in the chamber 10. The holes and he outer circumference of the tube paths 16 and 17 are sealed in-between with a sealing member to secure the airtightness inside the chamber 10.

The output setting unit 18 is a control device for setting the voltage or the current value between the anode 1 la and the cathode 13, and comprises a variable power source 18b. The anode 1 la and the cathode 13 are connected to the output setting unit 18 by lead wires respectively. The lead wires pass through holes formed in the chamber 10. The holes passed through by the lead wires are sealed by a sealing member.

The output setting unit 18 further comprises a control unit 18a. The control unit 18a is connected to the radiation thermometer 15 by a lead wire. When activated, the control unit 18a adjusts the voltage or the current value between the anode 11a and the cathode 13, such that the temperature of the substrate 1 becomes a predetermined value, based on the temperature of the substrate 1 measured by the radiation thermometer 15.

Next, a film forming process of forming films on the substrate 1 to build a field emission electrode by using the DC plasma CVD apparatus of FIG. 1 will be explained.

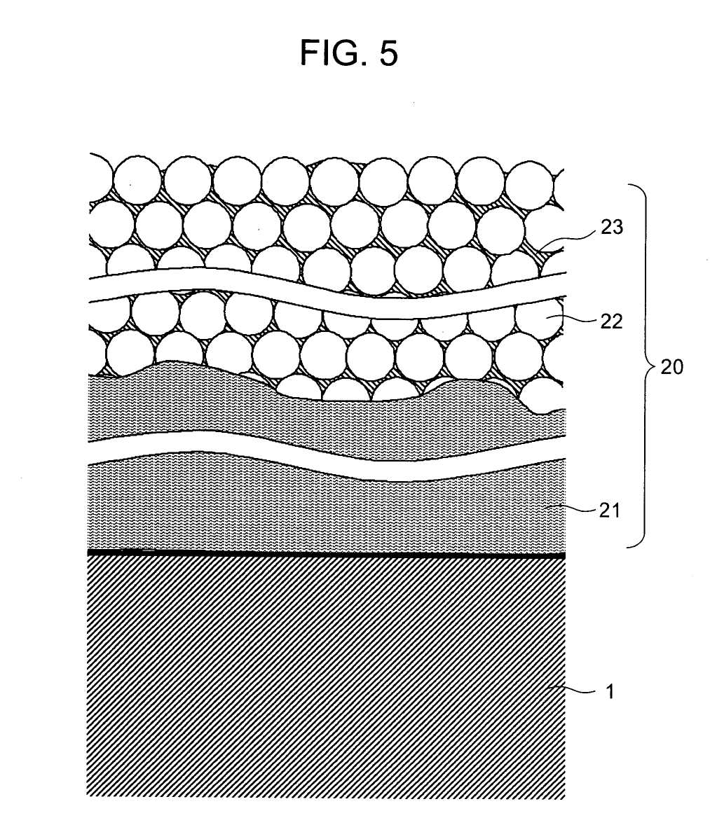

In this film forming process, an electron emission film 20 including a layer of carbon nanowall 21, and a layer formed on the layer of carbon nanowall 21 and containing a plurality of diamond fine grains 22 as shown in FIG. 5, will be formed on the surface of the substrate 1.

First, the electron emission film 20 will be explained.

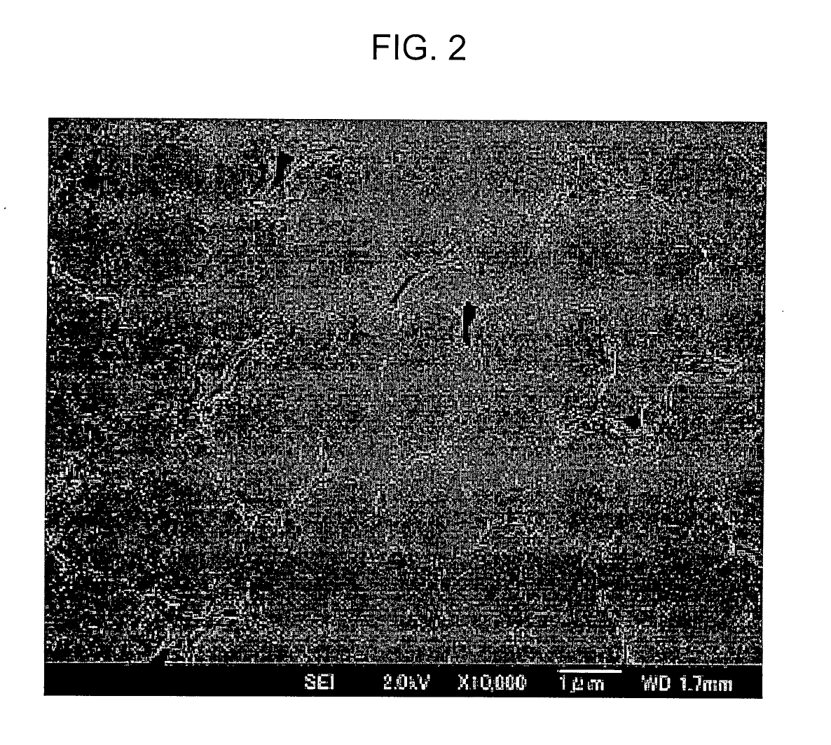

FIG. 2 is an image obtained by scanning the surface of the electron emission film 20 of FIG. 5 containing diamond fine grains 22, by using a scanning microscope.

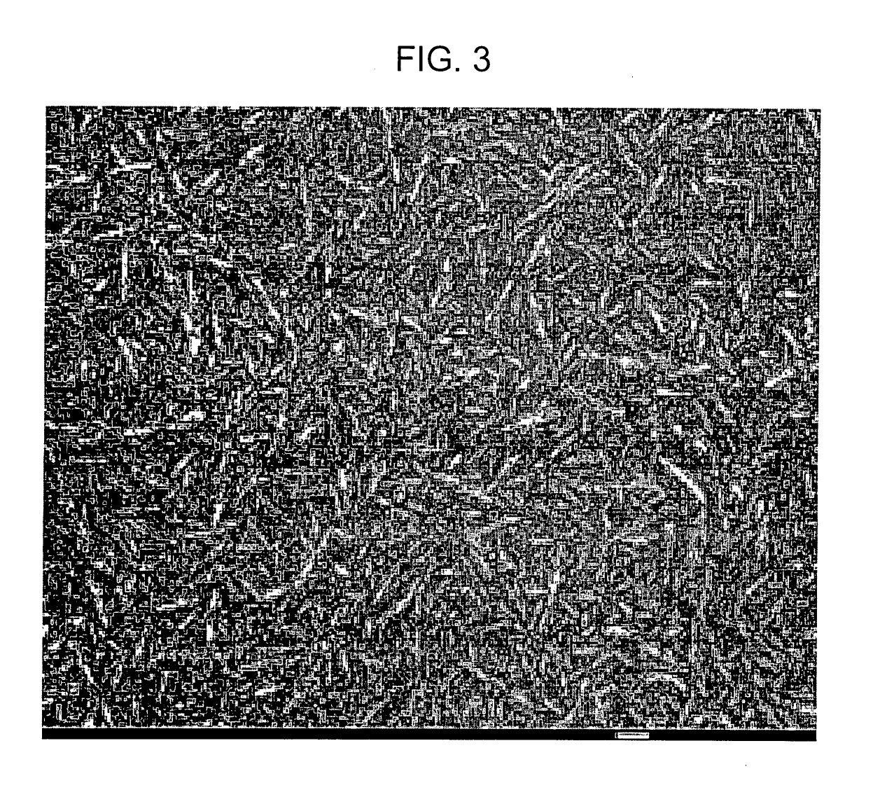

FIG. 3 is an image showing the electron emission film 20 of FIG. 2 in enlargement.

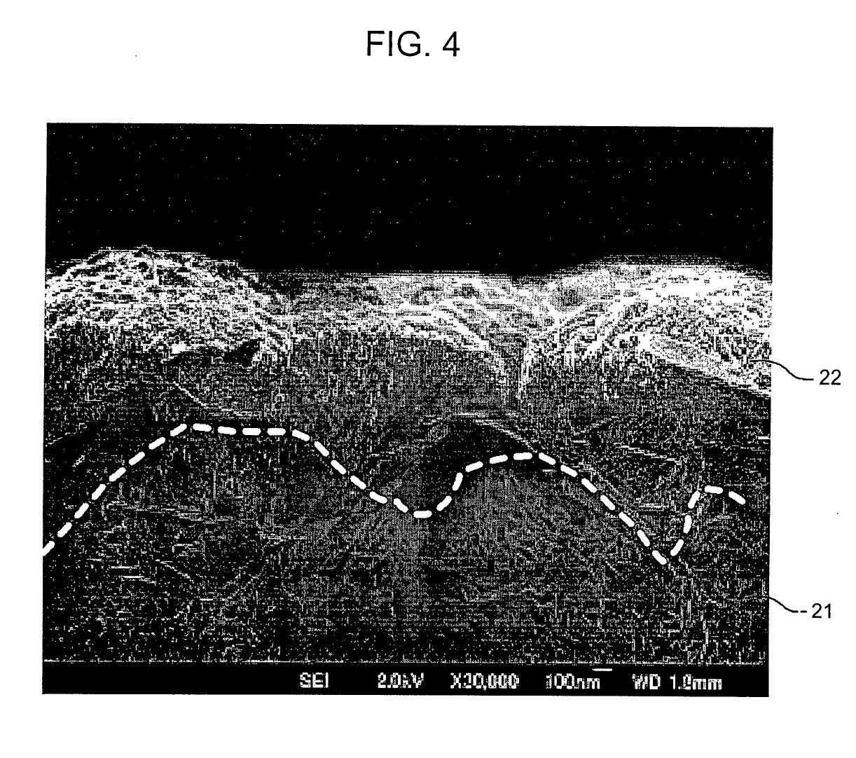

FIG. 4 is a secondary electron image showing a cross section of the electron emission film 20 and carbon nanowall 21 of FIG. 2.

The carbon nanowall 21 is formed of a plurality of carbon thin flakes of a petal (fan) shape having a curved surface which are uprightly bonded to the others in random directions, and has a thickness of 0.1 nm to 10 μm. Each carbon thin flake is formed of several to several tens of graphene sheets having a lattice interval of 0.34 nm. The graphene sheet contains sp² bonds and shows electric conductivity.

The electron emission film 20 contains the plurality of diamond fine grains 22 of sp³ bond having a grain diameter of 5 nm to 10 μm. The electron emission film 22 has an aggregate of several tens to several hundreds of diamond fine grains 22 in its surface, which form bamboo-leaf-like tissues as shown in FIG. 3. With a plurality of such bamboo-leaf-like tissues gathered, dense colonies whose surface is generally circular are formed in the surface of the electron emission film 20 and cover the carbon nanowall 21, as shown in FIG. 2. The colony diameter of the electron emission film 20 is about 1 μm to 5 μm, and it is preferable that the colonies are grown to such an extent enough to completely cover the carbon nanowall 21 with no uncovered portion left. Amorphous carbon 23 containing sp² bonds and showing electric conductivity exists in the gaps between the diamond fine grains 22. The carbon nanowall 21 has its upper surface relatively largely bossed or recessed, whereas the film containing the diamond fine grains 22 formed above has relatively relaxed bosses and recesses in its surface, and has a flattening characteristic. Therefore, many electron emission sites from which electrons are emitted by field emission can be formed in the surface of this film containing the diamond fine grains 22.

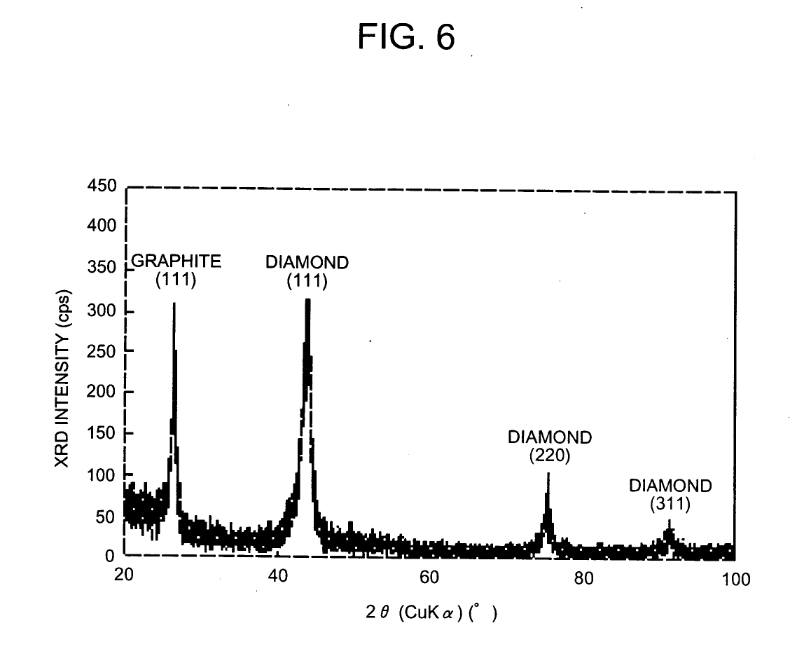

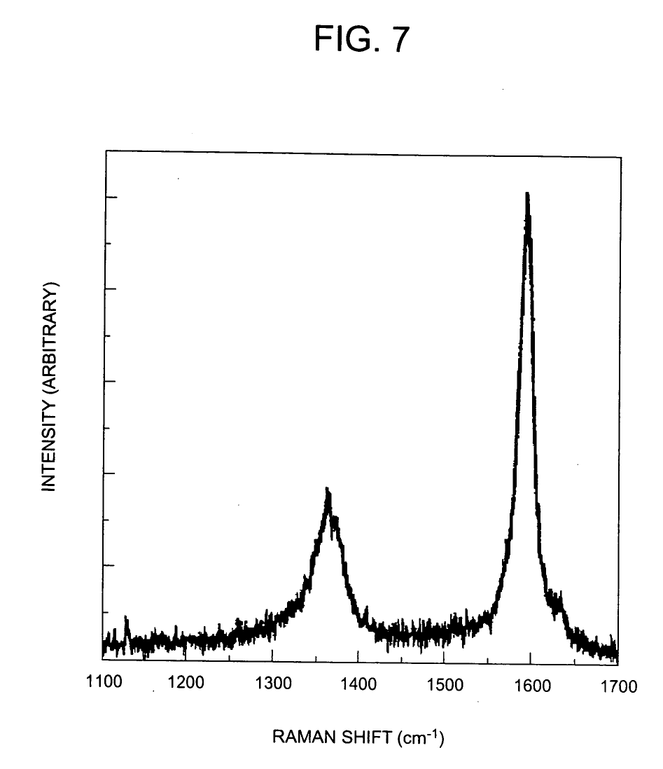

FIG. 6 is a diagram showing an X-ray diffraction pattern of the electron emission film 20. FIG. 7 is a diagram showing a spectrum of the carbon nanowall 21 forming the electron emission film 20, obtained by Raman spectroscopy.

Checking the X-ray diffraction pattern of the electron emission film 20, it was observed that the electron emission film 20 has conspicuous peaks attributed to diamond crystals, and also has a peak attributed to graphite at 20° to 30°, as shown in FIG. 6. Suppose that the direction of a normal line to the surface of the electron emission film 20 is 0°. It was found that as the direction in which the X-ray is radiated shifted from 0° to 90°, the intensity of the peak attributed to the graphite weakened and the peak substantially disappeared at near 90°, while the intensity of the conspicuous peaks attributed to the diamond crystals remained almost unchanged. Since the X-ray is more prohibited from entering the electron emission film 20 in the depth direction as the direction in which the X-ray is radiated becomes closer to the 90°, it was confirmed that he diamond structure was located in the surface layer and the graphite structure was located in the lower layer in the electron emission film 20.

Then, as shown in FIG. 7, there appeared a sharp intensity ratio between the peak in a G band near 1580 cm⁻¹ having a half-value width of less than 50 cm⁻¹ attributed to the vibration of carbon atoms within hexagon lattices formed by carbon-carbon bonds of the graphite, and the peak in a D band near 1350 cm⁻¹ having a half-value width of less than 50 cm⁻¹, and almost no other peaks were observed. From these facts, it is obvious that a carbon nanowall 21, which comprises carbon thin flakes formed of graphite of dense and highly pure sp² bonds, was grown.

Further, not only the diamond fine grains but also a film covered very thinly with diamond fine grains were found on the principal surface of the electron emission film 20. It was confirmed that this film was made of carbon which contains carbon of a graphite structure showing electric conductivity, judging from the fact that the resistance of a fine electron emission film 20 was several kΩ·cm and the composition of the material gas used in the manufacturing process. However, it can be understood that the amount of this film was very small relatively, because no conspicuous peak attributed to the amorphous carbon 23, which exists in the principal surface and between the diamond fine grains 22, was observed in the XRD spectroscopy. Thus, in the electron emission film 20, the above-described carbon containing carbon of sp² bonds of the graphite structure is formed in the topmost surface and between the diamond fine grains 22, and among these carbon atoms, those that has the graphite structure showing electric conductance contribute to lowering the resistance of the entire electron emission film 20.

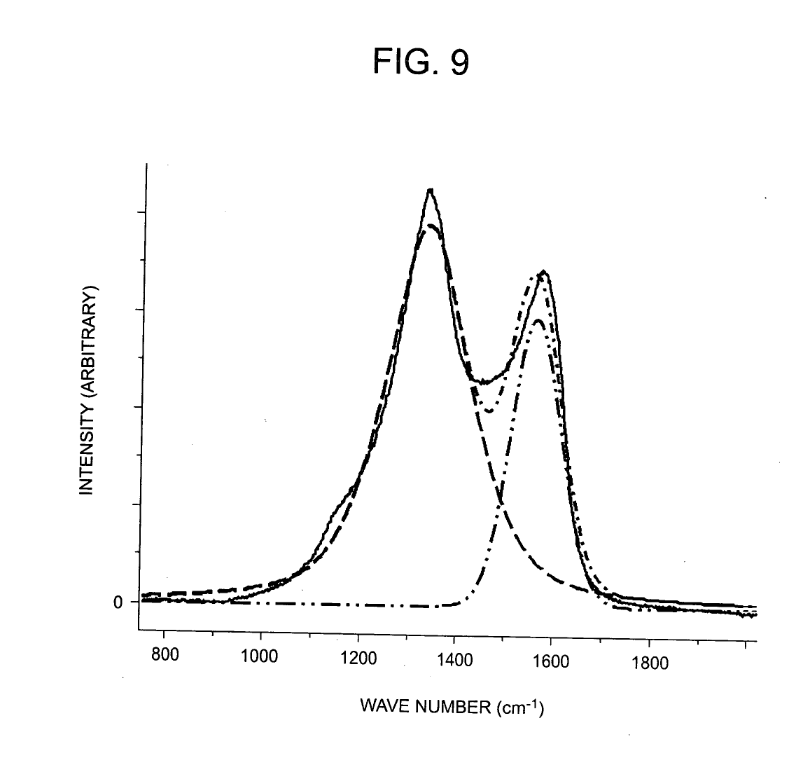

Conducting Raman spectroscopic measurement on the electron emission film 20 by using laser light having a wavelength of 532 nm, a peak of the diamond was observed near 1350 cm⁻¹ and a peak of the graphite was observed near 1580 cm⁻¹ as shown in FIG. 9, and it was confirmed that amorphous carbon mostly made of glassy carbon and graphite was mixed. The half-value width of the peak near 1350 cm⁻¹ is 50 cm⁻¹ or larger. That is, the electron emission film 20 was confirmed in the X-ray diffraction pattern to contain diamond having sp³ bonds and amorphous carbon having sp² bonds, and was confirmed in the Raman spectroscopy spectrum to contain amorphous carbon having a broad peak whose half-value width is 50 cm⁻¹ or larger. Therefore, it was clear hat the electron emission film 20 had a complex body of these. The spectrum shown in FIG. 9 will be described later.

A fine electron emission film 20 had a resistance of 1 kΩ·cm to 18 kΩ·cm. The aforementioned amorphous carbon (carbon having sp² bonds) 23 exists between the diamond fine grains 22. Since the amorphous bond 23 shows electric conductivity, it contributes to lowering the resistance of the entire electron emission film 20.

Next, the film forming process will be explained.

In the film forming process, first, the substrate 1 is cut out from, for example, a nickel plate, and well subjected to degreasing and ultrasonic cleaning using ethanol or acetone.

The substrate 1 is mounted on the anode 11a of the DC plasma CVD apparatus having the structure shown in FIG. 1A and FIG. 1B.

When the mounting of the substrate 1 is completed, the interior of the chamber 10 is depressurized by using the gas discharge system, and a gas of a compound (carbon-containing compound) which contains carbon in its composition, such as hydrogen gas, methane, etc. is introduced from the gas supply tube path 16.

It is preferred that the gas of the compound containing carbon in its composition be in the range of 3 vol % to 30 vol % of the entire material gas. For example, the mass flow of methane is set to 50 SCCM, the mass flow of hydrogen is set to 500 SCCM, and the entire pressure is set to 0.05 to 1.5 atm, preferably to 0.07 to 0.1 atm. The anode 11a is rotated together with the substrate 1 at 10 rpm, and a direct current is applied between the anode 11a and the cathode 13 to generate plasma. The state of the plasma is controlled, and also the temperature of the substrate 1 is controlled such that the unevenness in the temperature of the substrate 1 is restricted to within 5%.

In forming the carbon nanowall 21, the temperature of the region on the substrate 1 where the carbon nanowall 22 is to be formed is set to 900° C. to 1100° C. This temperature is measured by the radiation thermometer 15. At this time, the cooling member 12 is sufficiently spaced apart, so that the temperature of the anode 11a may not be affected. The radiation thermometer 15 is set to measure the temperature only from the heat radiation from the surface of the substrate 1, by subtracting the plasma radiation of the DC plasma CVD apparatus.

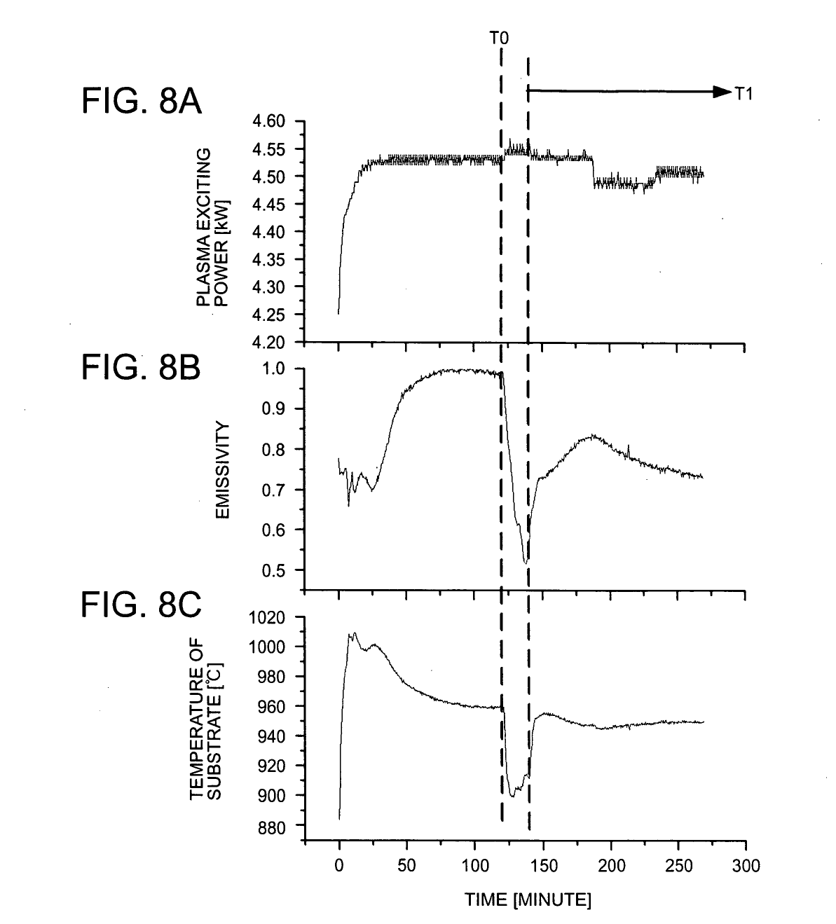

FIG. 8A to FIG. 8C show the temperatures on the surface of the substrate 1, which are calculated based on the power consumed, the emissivity observed at the surface of the substrate 1, etc. when plasma was excited by the DC plasma CVD apparatus. In FIG. 8A to FIG. 8C, the horizontal axis represents time, which is synchronous throughout the FIG. 8A to FIG. 8C.

When the carbon nanowall 21 to be the base layer is sufficiently formed, sequentially with the gas atmosphere remaining unchanged, the cooling member 12 having a temperature lower by far than that of the anode 11a, which has been heated by the plasma, is moved upward by 100 mm to abut on the stage 11 and cool the anode 11a (at timing T₀). At this time, the cooled anode 11a cools the substrate 1 fixed thereon, thus the surface of the substrate 1 is cooled rapidly down to a temperature suitable for forming the plurality of diamond fine grains 22, which is lower by 10° C. or more than that when the carbon nanowall 21 is formed. The temperature at this time is 890° C. to 950° C., ore more preferably, 920° C. to 940° C. Note that in order that the temperature may be stabilized for the succeeding steps, it is preferred that the voltage or the value of the current to be applied to the anode 11a and the cathode 13 be not changed greatly at the timing T₀.

Since the substrate 1 is cooled rapidly, the growth of the carbon nanowall 21 stops, and the plurality of diamond fine grains 22 start to grow from the carbon nanwall 21 as nuclei. In due course, the plurality of diamond fine grains 22 of sp³ bonds having a grain diameter of 5 nm to 10 nm, are formed on the carbon nanowall 21, and the amorphous carbon 23 of sp² bonds having electric conductivity are formed between the diamond fine grains 22.

According to the present embodiment, it is possible to drastically vary the film quality of the electron emission film 20 by rapid cooling, without much changing the voltage or the value of the current to be applied between the anode 11a and the cathode 13.

Though it is possible to grow the diamond fine grains 22 by, for example, changing only the voltage or the value of the current to be applied, it is not easy to drastically change the temperature within the chamber 10 depending on how the voltage or the value of the current to be applied is adjusted. Even if it should be able to lower the temperature, the temperature would violently fluctuate and it would be hard to maintain the temperature to the level suitable for forming the diamond fine grains 22. That is, the film quality of the electron emission film 20 will be worsened. Further, if the temperature is lowered gradually, the carbon nanowall 21 will not stop growing even if the temperature is decreased by 10° or more. This will slow down the growth of the diamond fine grains 22 and produce a layer in which the carbon nanowall and diamond fine grains are mixed. This means that it is difficult to drastically vary the film quality layer by layer, unlike the present embodiment.

Next, at a timing T₁, the cooling member 12 having abutted on the stage 11 is moved downward, thus the temperature of the surface of the substrate 1 is again raised by the plasma. At this time, if the temperature raising is up to 950° C., the diamond fine grains 22 and the amorphous carbon 23 will keep growing, without being replaced by a further growth of the carbon nanowall 21.

The layer, which includes the sufficiently grown plurality of diamond fine grains 22 and amorphous carbon 23, entirely covers the layer of the carbon nanowall 21, and its topmost surface is flattened as compared to the surface of the carbon nanowall 21. Though the electron emission film 20 which contains the diamond fine grains 22 could be formed even when the gas of the compound containing carbon atoms in its composition was less than 3 vol % of the entire material gas, it was confirmed that the electron emission characteristic of this film was extremely poor.

The radiation thermometer 15 used in the film formation has a problem that it cannot accurately measure the temperature in a case where the layer including the diamond fine grains 22 is directly formed on the substrate 1, because the metal that forms he substrate 1 reflects heat and the emissivity of that metal is wavelength-dependent, and he radiation from the electron emission film 20 would therefore be unstable. However, by using the carbon nanowall 21, which has an emissivity of 1 with no wavelength-dependency, as the base film, it is possible to set the emissivity of the diamond fine grains 22 to 0.7 when they are formed on the carbon nanowall 22, and to thereby measure the temperature stably.

Further, it is assumable that the cathode 13, when its temperature is raised by the plasma, might hinder the accurate measurement of the temperature of the substrate 1, because the radiation from the cathode 13 might be reflected on the substrate 1 and enter the radiation thermometer 15. However, by forcibly cooling the cathode 13 by circulating a cooling medium through the tube path 13b, the flow path 13a, and the tube path 13c, it is possible to shift the spectrum radiated from the cathode 13 to the longer wavelength side, so as not to allow the cathode 13 to hinder the measurement of the temperature of the substrate 1. Accordingly, it is possible to restrict unevenness in the temperature of the entire surface of the substrate 1.

At the ending steps in the film formation, the voltage application between the anode 11a and the cathode 13 is stopped. Then, the supply of the material gas is stopped, and nitrogen gas as a purge gas is supplied into the chamber 10 to restore the normal pressure. Then, the substrate 1, which has been restored to the normal temperature, is taken out.

Through the above-described steps, the electron emission film 20 shown in FIG. 5 is formed.

The layer of the carbon nanowall 21 is formed on the substrate 1 by maintaining the region where the carbon nanowall 21 is to be formed to a higher temperature than that for forming the layer of the diamond fine grains 22 and at 900° C. to 1100° C. for 30 minutes to 360 minutes by appropriately selecting conditions such as the mixing ratio of the material gas, the gas pressure, the bias gas to the substrate 1, etc. Then, the layer of the diamond fine grains 22 can subsequently be formed on the carbon nanowall 21, by lowering the temperature of the region where the layer of the diamond fine grains 22 is to be formed by 10° C. or more from the temperature for forming the carbon nanowall 21.

Though the carbon nanowall 21 has an excellent electron emission characteristic, it is difficult to form uniform emission sites thereon because the carbon nanowall 21 has bosses and recesses of several microns. However, by forming a layer comprising the diamond fine grains 22 on the carbon nanowall 21 as in the present embodiment, it is possible to obtain a uniform surface profile. Accordingly, uniform emission sites can be formed.

FIG. 9 shows a spectrum measured by Raman spectroscopy using laser light having a wavelength of 532 nm, where the solid line indicates the Raman spectrum of the aggregates of the plurality of diamond fine grains 22 and amorphous carbon 23 in the electron emission film 20. Since the electron emission film 20 has the carbon nanowall 21 under the diamond fine grains 22 and the diamond fine grains 22 are formed to an extent sufficient to cover the entire surface of the carbon nanowall 21, the spectrum of the diamond fine grains 22 is dominant.

Here, a peak of the diamond was observed near 1330 cm⁻¹, a peak of the graphite was observed near 1580 cm⁻¹, and it was confirmed that amorphous carbon mostly made of glassy carbon and graphite was mixed. The half-value width of the peak near 1330 cm⁻¹ is 50 cm⁻¹ or larger. That is, the electron emission film 20 was confirmed in the X-ray diffraction pattern to contain diamond and amorphous carbon in its composition and was confirmed in the Raman spectroscopy spectrum to contain amorphous carbon having a broad peak whose half-value width is 50 cm⁻¹ or larger. Therefore, it was clear that the electron emission film 20 had a complex body of these.

To precisely calculate a spectrum attributed to diamond and a spectrum attributed to graphite from this Raman spectrum, first, a spectrum portion ranging from 750 cm⁻¹ to 2000 cm⁻¹ is extracted from this spectrum drawn by the values which are the combinations of diamond spectrum and graphite spectrum, and with the line that connects both ends (the end near 750 cm⁻¹ and the end near 2000 cm⁻¹) of the extracted portion seen as a baseline, the values existing on the baseline (i.e., the values that represent noise) are eliminated from the spectrum. Then, a pseudo-Voigt function is placed such that the peak of the diamond spectrum to be substituted for position is set to 1333 cm⁻¹ as the initial value, and the peak of the graphite spectrum is set to 1580 cm⁻¹ as the initial value, and the spectrum is fitted to this function by nonlinear least-squares method.

In FIG. 9, the dashed line indicates the combined component of the D-band intensity and G-band intensity, in which the broken line indicates the D-band intensity component extracted from the combined component, and the double-dashed line indicates the G-band intensity component extracted.

In this manner, a ratio (D-band intensity)/(G-band intensity) is obtained from the area ratio between the D band whose peak is near 1333 cm⁻¹ and the G band whose peak is near 1580 cm⁻¹. The ratio (D-band intensity)/(G-band intensity) can be paraphrased as a ratio (the number of sp³ bonds in the film)/(the number of sp² bonds in the film), i.e., a ratio (carbon having sp³ bonds)/(carbon having sp² bonds).

Accordingly, although the carbon film upon the carbon nanaowall 21 is seemingly a single-layer film as a whole, it has, when microscopically seen, a structure of a complex film including the aggregates of diamond fine grains 22 formed of carbon of sp³ bonds indicated as D band and having a grain diameter of about 5 nm to 10 nm, and the amorphous carbon 23 having sp² bonds indicated as G band and existing in the gaps between the diamond fine grains 22.

Assuming that the thickness of the electron emission film 20 is 3 μm, several hundreds of diamond fine grains, which have a grain diameter of about 5 nm to 10 nm, are continuously stacked in the thickness-wise direction. These diamond fine grains 22 are each insulative, but the carbon of sp² bonds in the gaps of grains has electric conductivity, therefore the film as a whole has electric conductivity.

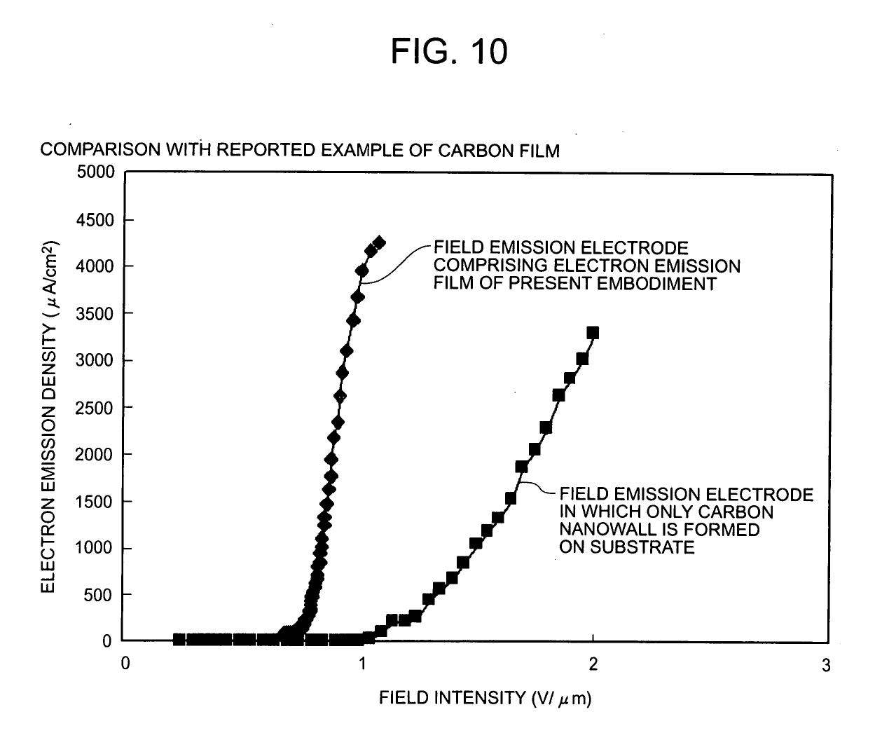

The field emission electrode, which comprises the electron emission film 20 in which the layer of the diamond fine grains 22 and amorphous carbon 23 is formed on the carbon nanowall 21 formed on the substrate 1, produced field emission at a field intensity of 0.84 V/μm when the current density was 1 mA/cm², which means that this electrode produced field emission at a lower voltage than a field emission electrode in which only a carbon nanowall having the same structure as the carbon nanowall 21 is formed, as obvious from FIG. 10 where a comparative example is shown. Thus it was confirmed that the field emission electrode comprising the electron emission film 20 had a more favorable electron emission characteristic. It was further confirmed that the field emission electrode comprising the electron emission film 20 had a more favorable electron emission characteristic than a case where the layer of the diamond fine grains 22 and amorphous carbon 23 was directly formed on the substrate 1.

The electron emission film 20 can emit electrons by a tunneling effect, because the individual diamond fine grains 22 in the film 20 have a negative electron affinity and are very small, having a grain diameter of 10 nm or smaller. Further, the electron emission film 20 is not only facilitated to produce field emission due to being provided with electric conductivity because of the existence of carbon having sp² bonds in the gaps between the diamond fine grains 22 at a predetermined rate of existence, but also structured such that the diamond fine grains 22 are not stacked so continuously that a tunneling effect cannot be produced. That is, for example, if about a hundred diamond fine grains having a grain diameter of 10 nm are stacked in a predetermined direction with almost no gaps therebetween, the diamond will seemingly have a thickness of 1000 nm, and will not substantially produce a tunneling effect. However, with carbon having sp² bonds showing electric conductivity existing in the gaps between the diamond fine grains, he diamond fine grains are separated from one another and can each produce a tunneling effect.

Therefore, electrons emitted from the substrate by a voltage being applied are once injected into nearest diamond fine grains, field-emitted from these diamond fine grains, and then again injected into diamond fine grains adjacent in the direction of the electric field. Such electron emission occurs repeatedly in the direction of the electric field, and the electrons are finally emitted form the topmost surface of the electron emission film.

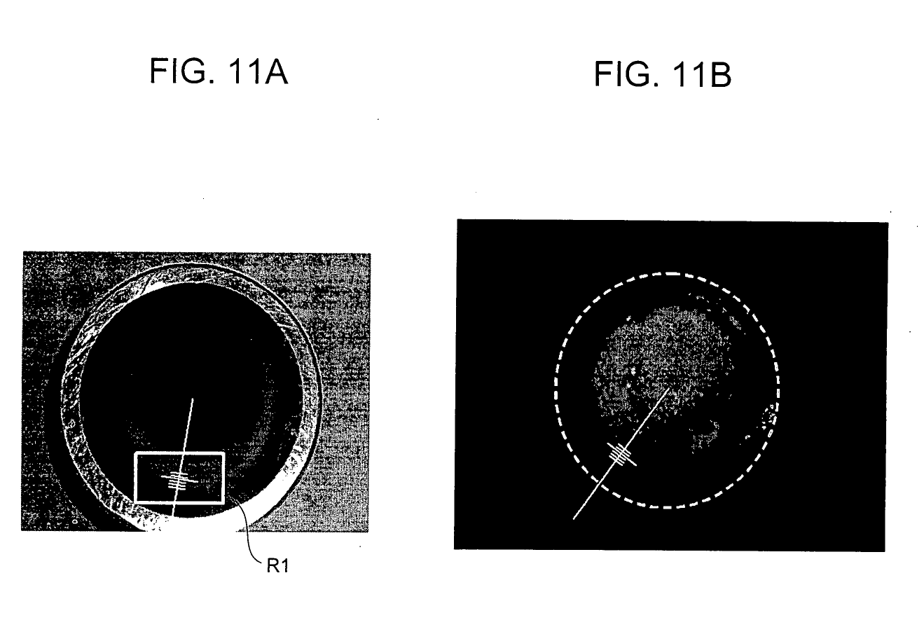

FIG. 11A is an image of the formed electron emission film 20. FIG. 11B is an image showing the state where a fluorescent material and a transparent conductor were positioned above the electron emission film 20 and light was excited from the fluorescent material due to the field emission of the electron emission film 20.

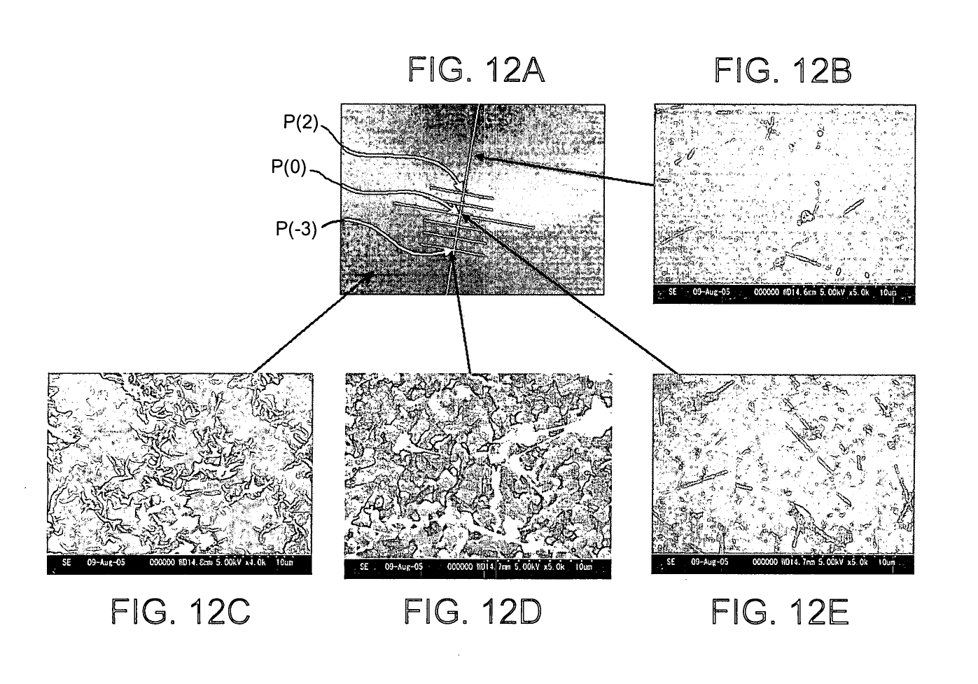

FIG. 12A is an enlarged image of a region R1 of FIG. 11A.

FIG. 12B is an image, obtained by a scanning electron microscope (SEM), showing a position indicated by an arrow of FIG. 12A, which is more inward than FIG. 12C, FIG. 12D, and FIG. 12E to be described later, and at which the most favorable field emission characteristic is obtained because the plurality of diamond fine grains 22 and the amorphous carbon 23 are densely gathered there upon the carbon nanowall 21 stacked on the substrate 1. At this position, the ratio (carbon having sp³ bonds)/(carbon having sp² bonds) was 2.55, and the grain diameter of the diamond fine grains 22 was 5 nm to 10 nm.

FIG. 12C is an SEM image showing a position indicated by an arrow of FIG. 12A, which is located more outward than FIG. 12B, FIG. 12D, and FIG. 12E in the electron emission film 20.

This position is where substantially only the carbon nanowall 21 was formed on the substrate 1, and the field emission characteristic was the poorest. This field emission characteristic was almost the same as that of the comparative example of FIG. 10. At this position, the ratio (carbon having sp³ bonds)/(carbon having sp² bonds) was 0.1.

FIG. 12D is an SEM image showing a position indicated by an arrow of FIG. 12A, which is located more outward than the position shown in FIG. 12B and more inward than the position shown in FIG. 12C.

At this position, the plurality of diamond fine grains 22 and the amorphous carbon 23 are stacked on the petal-like graphene sheets of the carbon nanowall 21 formed on the substrate 1, and gathered in spherical shapes. That is, one spherical body is constituted by multiple diamond fine grains. This sphere is formed when the diamond fine grains are grown on the tips of the grown petal-like graphene sheets. The electron emission characteristic at this position was better than the carbon nanowall of FIG.1 2C, but poorer than the film of FIG. 12B where the diamond fine grains 22 were densely gathered. At this position, the ratio (carbon having sp³ bonds)/(carbon having sp² bonds) was 0.5. Here, the grain diameter of the diamond fine grains was also 5 nm to 10 nm.

FIG. 12E is an SEM image showing a position indicated by an arrow of FIG. 12A, which is more outward than the position shown in FIG. 12B, and more inward than the position shown in FIG. 12D. At this position, crystalline growth of the diamond fine grains 22 and amorphous carbon 23 was more developed than at the position shown in FIG. 12D, so that the spherical bodies were linked together to make the film surface relatively smooth but with some gaps still remaining between spherical bodies. The electron emission characteristic here was better than that at the position shown in FIG. 12D, but slightly poorer than that of the film of FIG. 12B where the diamond fine grains 22 and the amorphous carbon 23 were densely gathered, but sufficient as the electron emission film 20. At this position, the ratio (carbon having sp³ bonds)/(carbon having sp² bonds) was 2.50. The grain diameter of the diamond fine grains were 5 nm to 10 nm.

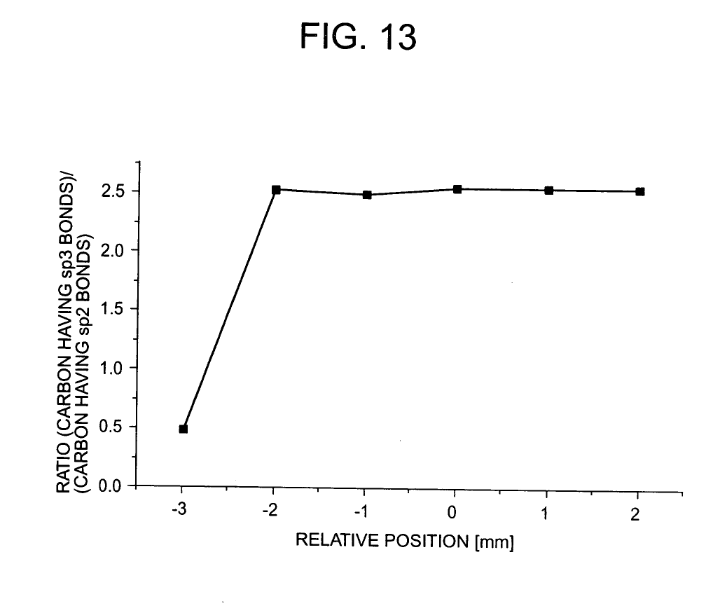

FIG. 13 shows the ratio (carbon having sp³ bonds)/(carbon having sp² bonds) at respective positions in the electron emission film 20, where assuming that the position P(0) shown in FIG. 12A as a relative position “0”, the positions reached by moving from the position P(0) toward the side of the position shown in FIG. 12B by 1 mm and 2 mm respectively are denoted as positions P(1) and P(2) respectively, and the positions reached by moving from the position P(0) toward the side of the position shown in FIG. 12D by 1 mm, 2 mm, and 3 mm respectively are denoted as positions P(−1), P(−2), and P(−3) respectively.

At a ratio (carbon having sp³ bonds)/(carbon having sp² bonds) of 2.5 and therearound, sufficient light emission was achieved at a low voltage, while at a ratio of 0.5, a relatively high voltage was required to achieve light emission. The ratio (carbon having sp³ bonds)/(carbon having sp² bonds) was 2.50 or higher, at positions at which the electron emission characteristic was particularly favorable.

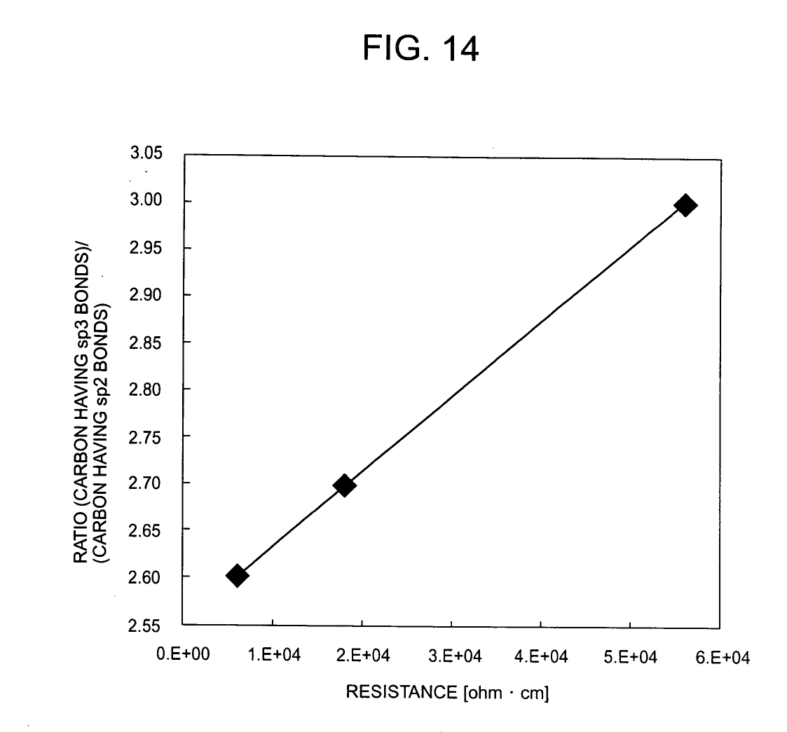

FIG. 14 is a graph showing the resistance in a case where the film was formed such that the ratio (carbon having sp³ bonds)/(carbon having sp² bonds) was shifted to a higher level.

An electron emission film 20 whose ratio (carbon having sp³ bonds)/(carbon having sp² bonds) was 2.6 had a resistance of 0.6×10⁴ (Ω·cm), and its electron emission characteristic was better than that of the electron emission film 20 whose ratio (carbon having sp³ bonds)/(carbon having sp² bonds) was 2.50 to 2.55.

An electron emission film 20 whose ratio (carbon having sp³ bonds)/(carbon having sp² bonds) was 2.7 had a resistance of 1.8×10⁴ (Ω·cm), and its electron emission characteristic was poor than that of the electron emission film 20 whose ratio (carbon having sp³ bonds)/(carbon having sp² bonds) was 2.6 but equal to that of the electron emission film 20 whose ratio (carbon having sp³ bonds)/(carbon having sp² bonds) was 2.55, and sufficient for a field emission electrode.

An electron emission film 20 whose ratio (carbon having sp³ bonds)/(carbon having sp² bonds) was 3.0 had a resistance of 5.6×10⁴ (Ω·cm), and its electron emission characteristic was poorer than that of the electron emission film 20 whose ratio (carbon having sp³ bonds)/(carbon having sp² bonds) was 2.50. This is because, in addition to the electric conductivity being lowered due to the reduced ratio of existence of carbon having sp² bonds, the film thickness of diamond became seemingly thicker due to the amorphous carbon 23 having sp² bonds becoming scarcer in the gaps between the diamond fine grains 22 to thereby reduce the rate of portions, from which tunnel electrons were effectively emitted.

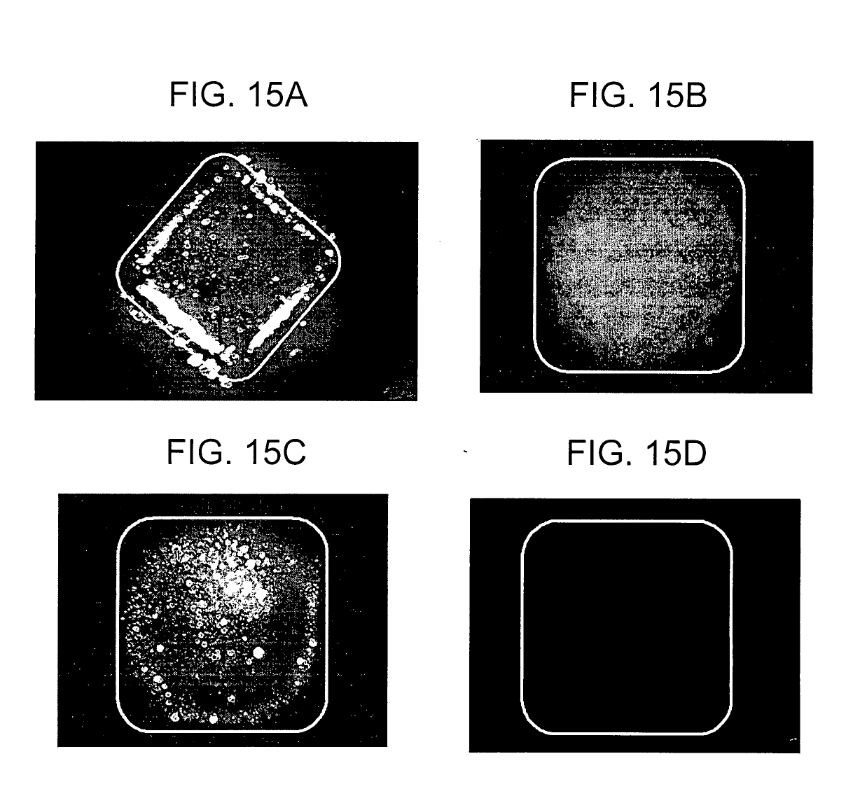

FIGS. 15A to 15D are images showing states that an anode electrode was arranged at a position 4.5 mm apart from a cathode electrode, which comprises the electron emission film 20 according to the present invention, and a 6 kV-pulse voltage (1 kHz, duty ratio: 1%), was applied across the anode electrode and the cathode electrode to cause a fluorescent body, which was arranged at the side of the anode electrode, to emit light.

FIG. 15A shows a case where the resistance of the electron emission film 20 was 1 kΩ·cm. FIG. 15B shows a case where the resistance of the electron emission film 20 was 6 kΩ·cm. FIG. 15C shows a case where the resistance of the electron emission film 20 was 18 kΩ·cm. FIG. 15D shows a case where the resistance of the diamond film was 56 kΩ·cm. It was confirmed that the electron emission film 20 of FIG. 15D produced light emission by a stronger electric field being applied. The ratio (carbon having sp³ bonds)/(carbon having sp² bonds) of the electron emission film 20 was 2.5.

After such electron emission films 20 were repeatedly manufactured, it was found out that electron emission films 20 from which a favorable electron emission characteristic was obtained had a ratio (carbon having sp³ bonds)/(carbon having sp² bonds) of 2.5 to 2.7, and particularly, electron emission films 20 from which such a favorable electron emission characteristic as would restrict the threshold field strength to 1.5 V/μm or lower was obtained had a ratio (carbon having sp³ bonds)/(carbon having sp² bonds) of 2.55 to 2.65. Further, electron emission films 20 which were stable and had a favorable electron emission characteristic had a ratio (carbon having sp³ bonds)/(carbon having sp² bonds) of 2.60 to 2.62.

In terms of resistance, electron emission films 20 having a resistance of 1 kΩ·cm to 18 kΩ·cm had a favorable electron emission characteristic.

A light source that comprises the electron emission film of the present invention can e applied to an FED (Field Emission Display), a backlight for a liquid crystal panel, and other light sources for home-use, or can be applied to a backlight for a personal computer, a digital camera, a cellular phone, etc., and a vehicle-mountable light source.

As described above, since the DC plasma CVD apparatus according to the present embodiment is so structured as to make the cooling member 12 abut on the stage 11 to rapidly cool the anode 11a, it can speedily change the quality of the carbon film and form a field emission electrode excellent in the electron emission characteristic. Further, by making the cooling member 12 abut on the anode 11a or separating it therefrom, the DC plasma CVD apparatus can cool the anode 11a more easily and more rapidly than a water-cooling system and can therefore control the temperature of the substrate 1 more easily.

Further, since the cathode 13 is a water-cooled one, it is possible to reduce the influence of the temperature of the cathode 13 in measuring the temperature of the substrate 1 using the radiation thermometer 15 and controlling the temperature of the substrate 1 by feedbacking the result of measurement, contributing to appropriately controlling the temperature of the substrate 1.

In the above-described embodiment, a case has been explained, in which the substrate 1 is cooled by the cooling member 12. However, this is not the only case. For example, as will be explained below, the substrate 1 may be cooled by the cooling member 12 and a cooling gas.

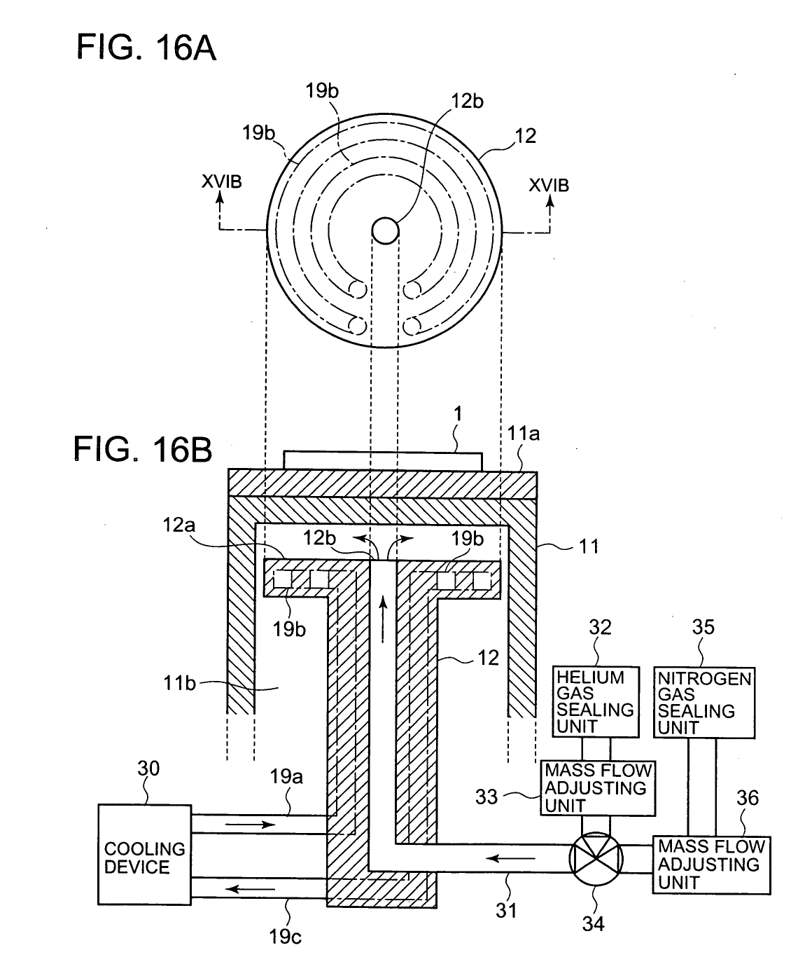

FIG. 16A is a top plan view showing a modified example of the cooling member 12 of the DC plasma CVD apparatus. FIG. 16B is an approximate cross sectional view of he DC plasma CVD apparatus as taken along a line XVIB-XVIB of FIG. 16A. The elements that are substantially the same as those in the above-described embodiment will be denoted by the same reference numerals, and a detailed explanation for such elements will be omitted.

A cooling member 12 is provided in a space 11 b enclosed by a stage 11. A surface 12a of the cooling member 12 has a vent hole 12b in the center, and the vent hole 12b is linked to a tube 31 provided in the cooling member 12. A three-way valve 34 is connected to the tube 31 and to a helium gas sealing unit 32 in which helium gas is sealed, through a mass flow adjusting unit. The three-way valve 34 is further connected to a nitrogen gas sealing unit 35 in which dried nitrogen gas is sealed, through a mass flow adjusting unit 36. The mass flow adjusting unit 33 has a pump for controlling the amount of helium gas to be supplied from the helium gas sealing unit 32, and can control the mass flow of helium gas having a room temperature to 0 to 1 (/1 min.). The mass flow adjusting unit 36 has a pump for controlling the amount of nitrogen gas to be supplied from the nitrogen gas sealing unit 35, and can control the mass flow of nitrogen gas having a room temperature to 0 to 22 (/1 min.). The mass flow adjusting unit 33, the mass flow adjusting unit 36, and the three-way valve 34 are controlled by a control unit 18a of an output setting unit 18.

In order that the surface 12a may be cooled to a uniform temperature, flow paths 19b in the cooling member 12 are shaped into a generally circular (arc) shape along with the shape of the surface 12a, and provided plurally so as to be concentric about the vent hole 12b. By circulating a cooling medium from a tube path 19a into the flow paths 19b in the cooling member 12 and flowing it as indicated by an arrow to be distributed uniformly and entirely in the cooling member 12, it is possible to cool the surface 12a uniformly and further cool the substrate 1 uniformly in the surface direction. The cooling medium discharged from a tube path 19c is cooled down again by a cooling device 30 and circulated so as to be conveyed to the tube path 19a again.

Further, by supplying helium gas and/or nitrogen gas from the vent hole 12b, it is possible to rapidly cool an anode 11 a on the stage 11.

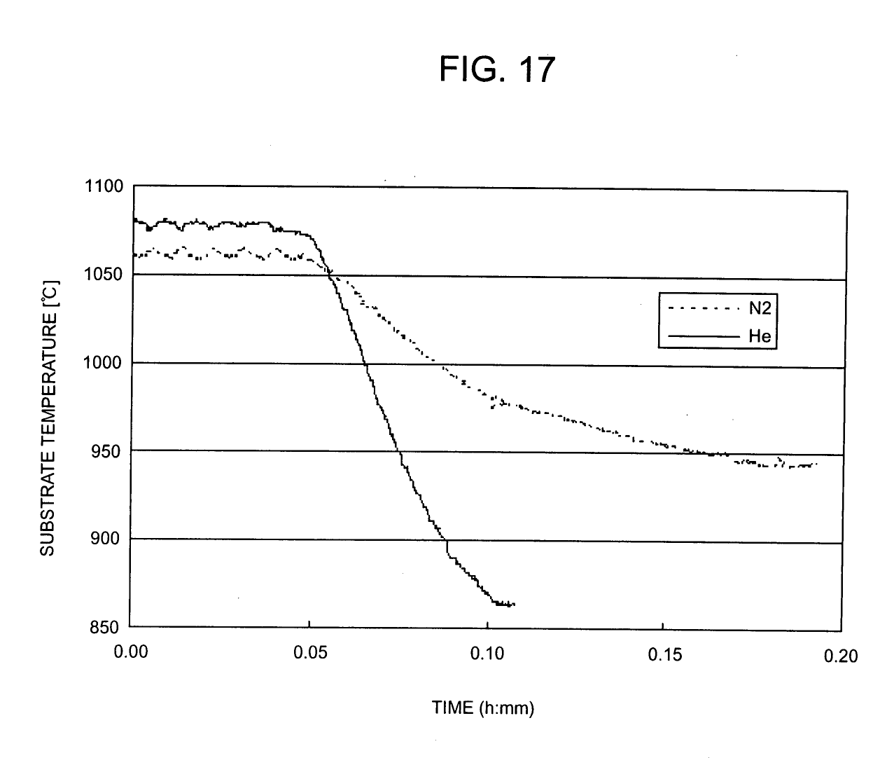

FIG. 17 is a graph in which the temperature of the surface of the substrate 1 is compared between a case where the gas to be supplied from the vent hole 12b was only helium gas, and a case where the gas to be supplied from the vent hole 12b was only nitrogen gas. Except that the gases to be supplied were different, conditions such as the current discharged by DC plasma, the material gas, the shape of the electrodes, etc. were the same in both the cases, and a radiation thermometer was used for measuring the temperature of the substrate 1. Until immediately before 5 minutes on the horizontal axis, DC plasma was generated and a carbon nanowall 21 was formed on the substrate 1 while the cooling member 12 did not abut on the stage 11, and when it became 5 minutes, the cooling member 12 was moved upward by 100 mm to make the surface 12a of the cooling member 12 abut on the stage 11. At this time, the cooling gas sent from the vent hole 12b was blown over the stage 11 and flew in the gap between the surface 12a and the stage 11 to assist in cooling the stage 11 and the substrate 1. By this cooling, the growth of the carbon nanowall 21 stopped and a layer including a plurality of diamond fine grains 22 started to grown on the carbon nanowall 21. In the case where the cooling gas was helium gas, the emissivity at the time of cooling was about 0.5.

Helium gas (having thermal conductivity of 150×10⁻³ (W/m·K)) is more excellent in thermal conductivity than nitrogen gas (having thermal conductivity of 260×10⁻⁴ (W/m·K)), and can cool the substrate 1, etc. rapidly. The cooling gas described above was set at a room temperature, but may not be set to a room temperature, as long as it is lower than the temperature for heating the substrate 1 when the carbon nanowall 21 is to be formed. Further, the cooling gas may be supplied immediately before the surface 12a of the cooling member 12 abuts on the stage 11, or when the surface 12a of the cooling member 12 abuts on the stage 11, or immediately after the surface 12a of the cooling member 12 abuts on the stage 11.

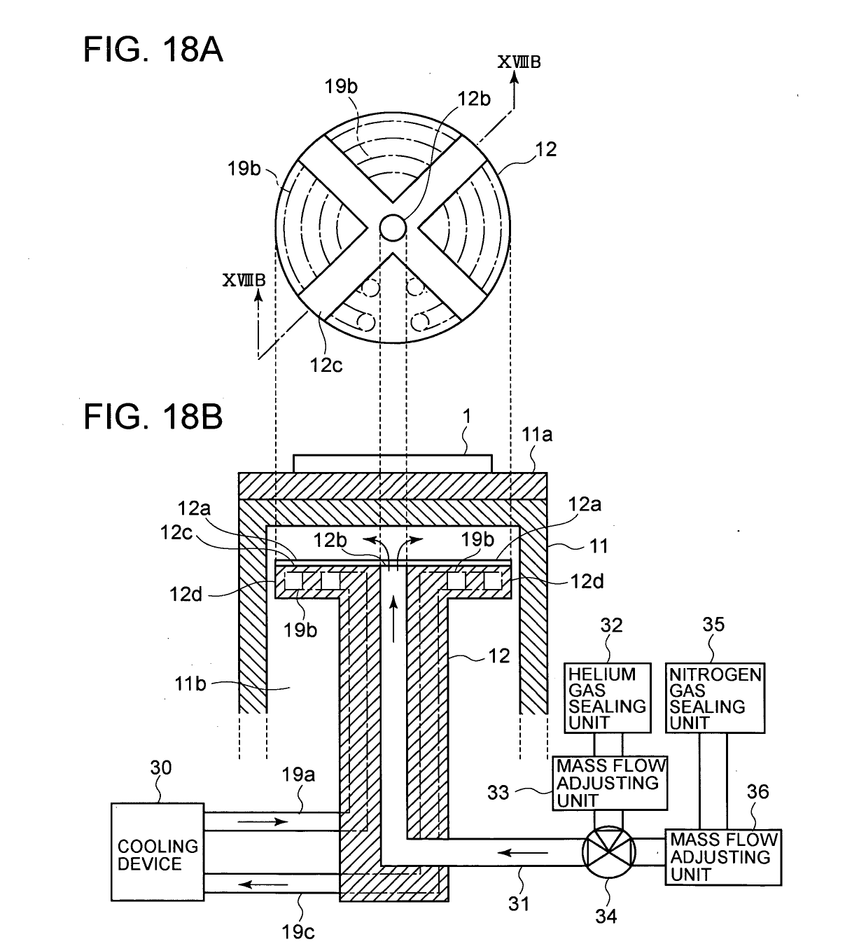

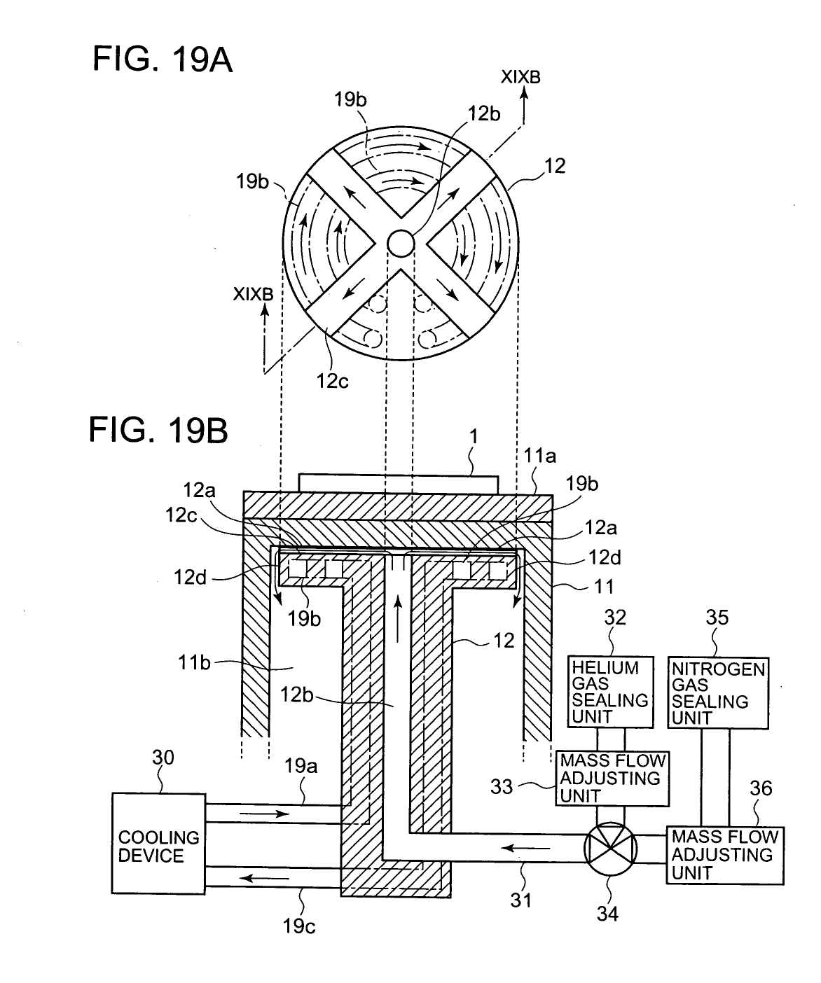

FIG. 18A is a top plan view showing another modified example of the cooling member 12 of the DC plasma CVD apparatus. FIG. 18B is an approximate cross sectional view of the DC plasma CVD apparatus as taken along a line XVIIIB-XVIIIB of FIG. 18A. Further, FIG. 19A is a top plan view showing the movement of the cooling member 12 when the DC plasma CVD apparatus is in the cooling operation. FIG. 19B is an approximate cross sectional view as taken along a line XIXB-XIXB of FIG. 19A.

While the surface 12a of the cooling member 12 is flat in the plasma CVD apparatus shown in FIG. 16A and FIG. 16B, grooves 12c are formed in the surface 12a of the cooling member 12 of the plasma CVD apparatus shown in FIG. 18A and FIG. 18B, such that the grooves 12c extend from a vent hole 12b to a side surface 12d of the cooling member 12. Therefore, as shown in FIG. 19B, even when the surface 12a of the cooling member 12 abuts on the stage 11, the cooling gas can move as indicated by the arrows through the flow paths formed in the gap between the grooves 12c and the stage 11 and effectively cool the substrate 1, etc.

In the above-described embodiments, the cooling gas is directly blown over the abutted surface of the stage 11. However, this is not the only case. The same effect can be obtains when the cooling gas is sealed in the space 11b enclosed by the stage 11.

The present invention is not limited to the above-described embodiments, but can be modified in various manners.

For example, the substrate 1 may include at least one of rare earth, copper, silver, gold, platinum, and aluminum, other than nickel.

The mixture ratio of hydrogen gas as the material gas, and the compound containing carbon may be selectively changed.

Further, in the above-described embodiments, an electron emitting electrode is formed. However, the present invention can also be applied to cases where other electronic components are formed by sequential plasma CVD, and is effective in cases here complex films having different film qualities are sequentially formed.

In the above-described embodiments, the electrode on which the substrate 1 is mounted is the anode, and the cathode is arranged above the anode. Instead, the electrode on which the substrate 1 is mounted may be the cathode, and the anode may be arranged above the cathode. In this case, by the cooling member 12 cooling the cathode, an electron emission film having a favorable quality can be manufactured.

Further, in the plasma CVD apparatus shown in FIGS. 16A and 16B or FIGS. 18A and 18B, as long as the cooling ability of the cooling gas can be sufficiently secured, the stage 12a of the cooling member 12 may not fully abut on the stage 11, but may be brought so close to the stage 11 that one part of the surface 12a may abut on the stage 11 but the other part of the surface 12a may not abut on the stage 11, or may be brought so close to the stage 11 that the entire surface 12a may not abut on the stage 11 in cooling the anode 11a.

Furthermore, in the above-described embodiments, the anode 11a may be integrated with the stage 11, so that the stage serving as the anode may be cooled by the cooling member 12.

According to the present invention, it is possible to securely realize a surface treatment utilizing plasma. Accordingly, it is possible to stably and securely manufacture, for example, a field emission electrode excellent in the field emission characteristic.

Various embodiments and changes may be made thereunto without departing from the broad spirit and scope of the invention. The above-described embodiments are intended to illustrate the present invention, not to limit the scope of the present invention. The scope of the present invention is shown by the attached claims rather than the embodiments. Various modifications made within the meaning of an equivalent of the claims of the invention and within the claims are to be regarded to be in the scope of the present invention.

This application is based on Japanese Patent Application No. 2005-289193 filed on Sep. 30, 2005 and Japanese Patent Application No. 2006-247972 filed on Sep. 13, 2006, and including specification, claims, drawings and summary. The disclosure of the above Japanese Patent Application is incorporated herein by reference in its entirety.

What is claimed is:

1. A plasma CVD apparatus, comprising:
a mount table having a mount surface on which a process target is mounted, and a first electrode;
a second electrode facing the first electrode for generating plasma between itself and the first electrode;
a voltage setting unit which applies a voltage between the first electrode and the second electrode; and
a cooling member which takes away heat from the process target.

2. The plasma CVD apparatus according to claim 1, comprising
a temperature measuring unit which measure a temperature of the process target.

3. The plasma CVD apparatus according to claim 1,
wherein while a first film is growing on the process target by plasma, the cooing member is made to abut on the mount table to cool the mount table, so that a second film different from the first film may be grown on the first film.

4. The plasma CVD apparatus according to claim 1,
wherein while a first film is growing on the process target by plasma, the cooling member is brought close to the mount table to cool the mount table, so that a second film different from first film may be grown on the first film.

5. The plasma CVD apparatus according to claim 1,
wherein a first film is grown on the process target by plasma before the cooling member takes away heat from the process target, and a second film different from the first film is grown on the first film by plasma after the cooling member takes away heat from the process target.

6. The plasma CVD apparatus according to claim 5,
wherein the first film comprises a carbon nanowall.

7. The plasma CVD apparatus according to claim 5,
wherein the second film contains diamond fine grains.

8. The plasma CVD apparatus according to any one of claims 1 to 7,
wherein the cooling member lowers a temperature of the process target by 10° C. or more.

9. The plasma CVD apparatus according to claim 1, comprising
a cooling member moving mechanism which moves the cooling member toward a surface of the mount table that is opposite to the mount surface.

10. The plasma CVD apparatus according to claim 9,
wherein the cooling member moving mechanism brings close the cooling member to or makes the cooling member abut on the mount table after a first film is grown on the process target by plasma, and moves the cooling member away from the mount table when the mount table is cooled to a predetermined temperature.

11. A plasma surface treatment method, comprising procedures of:
generating plasma between a first electrode and a second electrode to apply a first process on a surface of a process target mounted on a mount surface of a mount table; and
taking away heat from the process target by using a cooling member, and applying a second process on the surface of the process target.

12. The plasma surface treatment method according to claim 11,
wherein in the second process, the cooling member is made to abut on the mount table to cool the mount table while a first film is growing on the process target by plasma, and to grow a second film different from the first film on the first film.

13. The plasma surface treatment method according to claim 11,
wherein in the second process, the cooling member is brought close to the mount table to cool the mount table while a first film is growing on the process target by plasma, and to grow a second film different from the first film on the first film.

14. The plasma surface treatment method according to claim 11,
wherein in the first process, a first film is grown on the process target by plasma before the cooling member takes away heat from the process target, and in the second process, a second film different from the first film is grown on the first film by plasma after the cooling member takes away heat from the process target.

15. The plasma surface treatment method according to claim 14,
wherein the first film comprises a carbon nanowall.

16. The plasma surface treatment method according to claim 14,
wherein the second film contains diamond fine grains.

17. The plasma surface treatment method according to claim 11,
wherein the second process comprises lowering a temperature of the process target by 10° C. or more by using the cooling member.

18. The plasma surface treatment method according to claim 11,
wherein the second process comprises a cooling member moving process of moving he cooling member toward a surface of the mount table that is opposite to the mount surface.

19. The plasma surface treatment method according to claim 18,
wherein in the cooling member moving process, the cooling member is brought close to or made to abut on the mount table after a first film is grown on the process target by plasma, and the cooling member is moved away from the mount table when the mount table is cooled to a predetermined temperature.

20. A plasma surface treatment method, comprising procedures of:
generating plasma between a first electrode and a second electrode to form a first film comprising a carbon nanowall on a surface of a process target mounted on a mount surface of a mount table; and
taking away heat from the process target by using a cooling member, and forming a second film containing diamond fine grains on the first film.
